(19) United States
(12) Patent Application Publication
(10) Pub. No.: US 2025/0361647 A1
(43) Pub. Date: Nov. 27, 2025

(54) UV ENERGY SOURCES FOR PROCESSING CHAMBERS, AND RELATED APPARATUS AND METHODS

(71) Applicant: Applied Materials, Inc., Santa Clara, CA (US)

(72) Inventors: Joe MARGETIS, Gilbert, AZ (US); Abbas RASTEGAR, Schenectady, NY (US); Aaron Michael DANGERFIELD, Sunnyvale, CA (US); John TOLLE, Gilbert, AZ (US); Shawn THOMAS, Chesterfield, MO (US); Shu-Kwan LAU, Sunnyvale, CA (US)

(21) Appl. No.: 19/214,176

(22) Filed: May 21, 2025

Related U.S. Application Data
(60) Provisional application No. 63/650,119, filed on May 21, 2024.

(51) Int. Cl. C30B 30/00; C23C 16/458; C23C 16/46; C23C 16/48; C23C 16/50; C30B 25/10; C30B 25/14; H01J 37/32

(52) U.S. Cl. CPC C30B 30/00; C23C 16/4583; C23C 16/46; C23C 16/48; C23C 16/50; C30B 25/10; C30B 25/14; H01J 37/32357

(57) ABSTRACT

The present disclosure relates to UV light sources and/or processing activation in processing chambers, and related apparatus and methods. In one or more embodiments, a processing chamber applicable for semiconductor manufacturing includes a chamber body and a lid. The lid and the chamber body at least partially define an internal volume. The processing chamber further includes a substrate support disposed in a processing volume of the internal volume and a gas inlet fluidly coupled to the chamber body to provide gas to the internal volume. The gas inlet includes one or more UV energy sources for irradiating gas within the inlet prior to the gas entering the processing volume. The one or more UV energy sources comprise a first UV energy source having a first peak wavelength and second UV energy source having a second peak wavelength different from the first wavelength.

### CROSS-REFERENCE TO RELATED APPLICATIONS

This application claims priority to United States Provisional Patent Application Ser. No. 63/650,119 filed May 21, 2024, which are herein incorporated by reference in its entirety.

### BACKGROUND

### Field

The present disclosure relates to UV light sources and/or processing activation in processing chambers, and related apparatus and methods.

### Description of the Related Art

Semiconductor substrates are processed for a wide variety of applications, including the fabrication of integrated devices and microdevices. During processing, various parameters can affect the uniformity of material deposited on the substrate. For example the material can be deposited on other components besides the substrate, which can hinder deposition uniformity and deposition efficacy. Moreover, selective processing can be difficult. Additionally, it can be difficult to use relatively low substrate temperatures for processing operations.

Therefore, a need exists for improved chamber components that selectively deposit and/or etch material on the substrate.

### SUMMARY

The present disclosure relates to UV light sources and/or processing activation in processing chambers, and related apparatus and methods.

In one or more embodiments, a processing chamber applicable for semiconductor manufacturing includes a chamber body and a lid. The lid and the chamber body at least partially define an internal volume. The processing chamber further includes a substrate support disposed in a processing volume of the internal volume and a gas inlet fluidly coupled to the chamber body to provide gas to the internal volume. The gas inlet includes one or more UV energy sources for irradiating gas within the inlet prior to the gas entering the processing volume. The one or more UV energy comprise a first UV energy source having a first peak wavelength and a second UV energy source having a second peak wavelength different from the first peak wavelength.

In one or more embodiments, a method of substrate processing includes heating a substrate positioned on a substrate support, flowing one or more process gases over the substrate, and irradiating the one or more process gases with a first UV light having a first peak wavelength. The method further includes depositing one or more first film portions on the substrate using the one or more process gases irradiated with the first UV light, irradiating the one or more process gases with a second UV light having a second peak wavelength different than the first peak wavelength, and depositing on or more second film portions on the substrate using the one or more process gases irradiated with the second UV light. The second film portion has a different atomic composition from the first film portion.

In one or more embodiments, a non-transitory computer readable medium includes instructions that when executed by a processor of a system cause the system to heat a substrate positioned on a substrate support, flow one or more process gases over the substrate, and irradiate the one or more process gases with a first UV light having a first peak wavelength. The instructions further cause the system to deposit one or more first film portions on the substrate using the one or more process gases irradiated with the first UV light, irradiate the one or more process gases with a second UV light having a second peak wavelength different than the first peak wavelength, and deposit on or more second film portions on the substrate using the one or more process gases irradiated with the second UV light. The second film portion has a different atomic composition from the first film portion.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, for the disclosure may admit to other equally effective embodiments.

FIG. 1 is a schematic side cross-sectional view of a processing chamber, according to one or more embodiments.

FIG. 2 is a partial schematic side cross-sectional view of a processing chamber, according to one or more embodiments.

FIG. 3 is a partial schematic top cross-sectional view of the processing chamber shown in FIG. 2, according to one or more embodiments.

FIG. 4 is a schematic flow chart view of a method of processing a substrate in a processing chamber, according to one or more embodiments.

FIG. 5A is a partial schematic top view of the processing chamber shown in FIG. 1, according to one or more embodiments.

FIG. 5B is partial schematic top view of a processing chamber, according to one or more embodiments.

FIG. 6 is a schematic flow chart view of a method of processing a substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to ultraviolet (UV) energy source configurations for processing chambers, and related chamber kits, apparatus, methods, and components for semiconductor manufacturing. In one embodiment which can be combined with other embodiments, the UV energy source is used to activate gases and/or surfaces in relatively low temperature epitaxial deposition operations.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

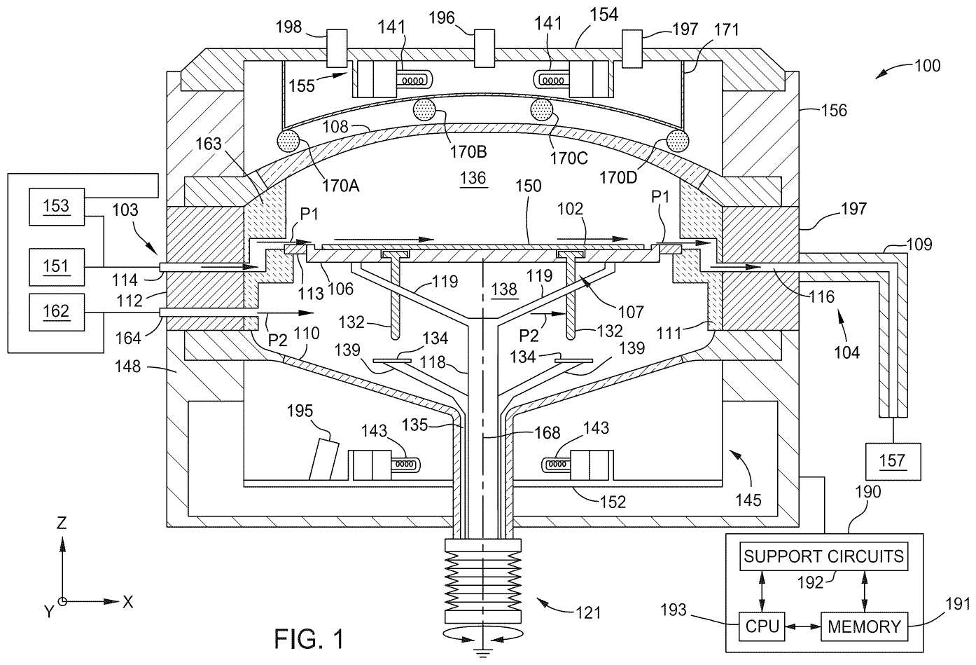

FIG. 1 is a schematic side cross-sectional view of a processing chamber 100, according to one or more embodiments. The processing chamber 100 is a deposition chamber. In one embodiment which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, a first plate 108 (such as an upper plate, e.g., an upper window for example an upper dome), a second plate 110 (such as a lower plate, e.g., a lower window for example a lower dome), and one or more heat sources 141, 143. The one or more heat sources 141, 143 include a plurality of upper heat sources 141 and a plurality of lower heat sources 143. The one or more heat sources 141, 143 are operable to heat the processing volume 136. In one embodiment which can be combined with other embodiments, the upper heat sources 141 include upper lamps (such as UV lamps and/or infrared lamps) and the lower heat sources 143 include lower lamps (such as UV lamps and/or infrared lamps). The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the first plate 108 and the second plate 110. The substrate support 106 supports the substrate 102. In one embodiment which can be combined with other embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the first plate 108 and a lid 154. The plurality of upper heat sources 141 form a portion of the upper heat source module 155.

The plurality of lower heat sources 143 are disposed between the second plate 110 and a floor 152. The plurality of lower heat sources 143 form a portion of a lower heat source module 145. The first plate 108 may be an upper dome and/or is formed of an energy transmissive material, such as quartz. At least part of the first plate 108 can be transmissive for ultraviolet light and/or opaque for infrared light. The second plate 110 may be a lower dome and/or is formed of an energy transmissive material, such as quartz.

A processing volume 136 and a purge volume 138 are formed between the first plate 108 and the second plate 110. The processing volume 136 and the purge volume 138 are part of an internal volume defined at least partially by the first plate 108, the second plate 110, and one or more liners 111, 163. The one or more liners 111, 163 are part of the chamber body.

The internal volume has the substrate support 106 disposed therein. The substrate support 106 includes a top surface on which the substrate 102 is disposed. The substrate support 106 is attached to a shaft 118. In one embodiment which can be combined with other embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136. In one or more embodiments, the shaft 118 is configured to rotate about the axis 168.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The flow module 112 is part of an inject section 103. The inject section 103 also includes the one or more gas inlets 114. The one or more gas inlets 114 and the one or more purge gas inlets 164 are disposed on the opposite side from the one or more gas exhaust outlets 116.

A pre-heat ring 113 is disposed below the one or more gas inlets 114 and the one or more gas exhaust outlets 116. The pre-heat ring 113 includes a complete ring or one or more ring segments. The pre-heat ring 113 is disposed above the one or more purge gas inlets 164. The one or more liners 111, 163 are disposed on an inner surface of the flow module 112 and protect the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H), Fluorine (F₂), and/or chlorine (Cl). In one embodiment which can be combined with other embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112. The one or more gas exhaust outlets 116 and the exhaust system 109 form an exhaust section 104. In one embodiment which can be combined with other embodiments, the inject section 103 is disposed on the opposite side of the process chamber 100 from the exhaust section 104.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The processing system includes one or more sensor devices 195, 196, 197, 198 (e.g., temperature sensors) configured to measure parameter(s) (e.g., temperature(s)) within the processing chamber 100. In one embodiment which can be combined with other embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one embodiment which can be combined with other embodiments, the one or more sensor devices 195, 196, 197, 198 each include a sensor that includes one or more of silicon (Si), carbon (C), gallium (Ga), and/or nitrogen (N). In one embodiment which can be combined with other embodiments, the one or more sensor devices 195, 196, 197, 198 each include a silicon sensor, a silicon carbide (SiC) sensor, and/or a gallium nitride (GaN) sensor. In one embodiment which can be combined with other embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature. In one embodiment which can be combined with other embodiments, one or more of the sensor devices 195, 196, 197, 198 can measure one or more gas parameters and/or one or more plasma parameters (such as ion density, electron temperature, electron density, ion energy and angle distribution, enthalpy, radical density, and/or absorption). In one embodiment which can be combined with other embodiments, one or more of the sensor devices 195, 196, 197, 198 include a residual gas analyzer, an optical emission spectrometer, an enthalpy probe, a Langmuir probe, a Faraday cup, and/or an absorption spectrometer.

In one embodiment which can be combined with other embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one embodiment which can be combined with other embodiments, the system including the process chamber 100 includes any one, any two, or any three of the four illustrated sensor devices 195, 196, 197, 198. In one embodiment which can be combined with other embodiments, the process chamber 100 includes one or more additional sensor devices, in addition to the sensor devices 195, 196, 197, 198. In one embodiment which can be combined with other embodiments, the process chamber 100 may include sensor devices disposed at different locations and/or with different orientations than the illustrated sensor devices 195, 196, 197, 198.

The processing chamber 100 includes one or more UV energy sources 170A, 170B, 170C, 170D. A plurality of UV energy sources 170A, 170B, 170C, 170D are shown. In one embodiment which can be combined with other embodiments, the UV energy sources 170A, 170B, 170C, 170D are disposed between the first plate 108 and the lid 154. In one or more embodiments a support structure 171 is used to support the UV energy sources 170A-D. The support structure 171 is coupled to the lid 154 and to each UV energy source 170A-D to support the UV energy sources 170A-D disposed above the first plate 108. It is contemplated that in one or more embodiments which can be combined with other embodiments, the support structure 171 is omitted and that the UV energy sources 170A-D can be disposed directly on top of the first plate 108. The UV energy sources 170A-D can also be directly coupled to the lid 154. In one embodiment which can be combined with other embodiments, at least one of the UV energy sources is operable to emit a UV light having a wavelength with a peak wavelength within a range of 160 nm to 450 nm. In one embodiment which can be combined with other embodiments, the peak wavelength of the UV light is within a range of 160 nm to 380 nm, such as a wavelength of 167 nm, 185 nm, 254 nm or 365 nm. The UV light has a photon energy of 12 eV or less, such as 4.5 or less or 4.0 or less. In one embodiment which can be combined with other embodiments, the photon energy is within a range of 2.5 eV to 12 eV, such as within a range of 3.0 eV to 4.8 eV. In one embodiment which can be combined with other embodiments, the photon energy is within a range of 2.75 eV to 7.75 eV. In one embodiment which can be combined with other embodiments, the photon energy is within a range of 3.1 eV to 3.7 eV, such as within a range of 3.3 eV to 3.4 eV. In one embodiment, which can be combined with other embodiments, the photon energy of the UV light is greater than 3.1 eV, such as within a range of 3.3 eV to 4.5 eV, for example within a range of 3.3 eV to 4.0 eV. The wavelength of each UV energy source 170A, 170B, 170C, 170D is able to be tuned independently from one another.

The photon energy of the UV light can correspond to the peak wavelength of the UV light based off of the equation: Photon energy (eV)=1.2398/(photon wavelength in microns). For example, a UV light with a peak wavelength of 160 nm can have a photon energy of 7.75 eV. As another example, UV light with a wavelength of 450 nm has a photon energy of 2.75 eV. The described photon energies can cause certain materials to be selectively excited by the UV photons relative to other materials. For example silicon (Si) can have a material band gap of about 3.3 eV to about 3.4 eV, and photon energies equal to or greater than that band gap will be absorbed by the silicon to generate electron-hole pairs that catalyze surface reactions. Processing gases such as silicon nitride (Si₃N₄) and silicon oxide (SiO₂) can have material band gaps of about 5 eV and about 9 eV respectively. Therefore, a UV energy source emitting a UV light with a photon energy of 3.5 eV would be selectively absorbed by and activates the silicon material in the processing gases P1. The UV light breaks the bonds with the silicon in the processing gases P1. This allows for the silicon to be selectively deposited on the substrate 102 while keeping the substrate 102 at a relatively low temperature such as a temperature under 500 degrees Celsius. It is contemplated that the UV energy sources 170A, 170B, 170C and 170D can be any type of energy source configured for emitting UV light such as UV lamps, LEDs, and/or lasers.

The present disclosure contemplates that the upper heat sources 141 and/or the lower heat sources 143 can be omitted. In one embodiment which can be combined with other embodiments, the upper heat sources 141 are omitted while the lower heat sources 143 are used in conjunction with the UV energy sources 170A-170D above the first plate 108.

In one embodiment which can be combined with other embodiments the UV energy sources 170A, 170B, 170C, 170D all emit the UV light at the same photon energy and/or the same wavelength. In one or more embodiments the UV light sources are configured to emit UV light at different photon energies and/or different wavelengths. For example, the UV energy sources 170A and 170B can be configured to emit a UV light at a wavelength having a photon energy of 3.4 eV and UV energy sources 170C and 170D can be configured to emit a UV light at a wavelength having a photon energy of 4.0 eV. In one or more embodiments, UV energy source 170A emits a UV light at a different wavelength from UV energy source 170B, which emits a UV light at a different wavelength from UV energy source 170C, which emits a UV light at a different wavelength from UV energy source 170D. It is contemplated that although the processing chamber 100 shows four UV energy sources, any number of UV energy sources could be used such as 1 UV energy source, 2 UV energy sources, 4 UV energy sources, 5 UV energy sources, or 8 UV energy sources.

In one embodiment which can be combined with other embodiments during the deposition operation the substrate 102 is heated to a temperature less than 500 degrees Celsius, such as within a range of 380 degrees Celsius to 450 degrees Celsius, for example about 400 degrees Celsius. The process gases P1 flow over the substrate 102 in the processing volume 136. The UV energy sources 170A, 170B, 170C, 170D emit UV light having a photon energy less than 12 eV, such as 7.75 eV or less. The UV light is absorbed by the process gases P1 and/or one or more surfaces of the substrate 102 to activate the process gases P1 so that the process gases selectively deposit a layer of material on certain surfaces of the substrate 102 relative to other surfaces of the substrate 102 and other components such as the liners 163, 111 and/or or the pre-heat ring 113.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102.

The controller 190 includes a central processing unit (CPU) 193 (e.g., a processor), a memory 191 containing instructions, and support circuits 192 for the CPU 193. The controller 190 controls various items directly, or via other computers and/or controllers. In one embodiment which can be combined with other embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., one or more wavelengths and/or photon energies of UV light emitted by the UV energy sources 170A-170D, a power applied to the heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations (such as the operations of the method 400) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the one or more heat sources 141, 143; the UV energy sources 170A, 170B, 170C, 170D; the deposition; the cleaning; the rotational position; the heating; and gas flow through the processing chamber 100 by providing an output to the controls for the sensor devices 195, 196, 197, 198, and/or the one or more heaters, the upper heat sources 141, the lower heat sources 143, the process gas source 151, the purge gas source 162, the motion assembly 121, and/or the exhaust pump 157.

The controller 190 is configured to adjust the output to the controls based on the sensor readings, a system model, and stored readings and calculations. The controller 190 includes embedded software and a compensation algorithm to calibrate measurements. The controller 190 can include one or more machine learning algorithms and/or artificial intelligence algorithms that estimate optimized parameters (such as the one or more wavelengths and/or photon energies of UV light emitted by the UV energy sources 170A-170D) for the uniformity analysis operations, the deposition operations, and/or the cleaning operations.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100 and/or method(s) relative to other aspects of the process chamber 100 and/or method(s) (such as the method 400). The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100 and/or method(s). For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method(s). The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, optimized parameters such as wavelengths and/or photon energies for UV light, target temperature(s), reading(s), signal difference(s), signal profile(s), heating power(s), adjustment factor(s), threshold ratio(s), range(s), and/or training range(s) with which the signal difference(s) are compared, a cleaning recipe, and/or a processing recipe.

In one or more embodiments, the controller 190 automatically conducts the operations described herein without the use of one or more machine learning algorithms and/or artificial intelligence algorithms. In one or more embodiments, the controller 190 compares measurements (such as readings and/or signal differences for temperature measurements) to data in a look-up table and/or a library to identify a set of the UV energy sources 170A-170D and/or adjust one or more wavelengths and/or photon energies for the set. The controller 190 can stored measurements as data in the look-up table and/or the library.

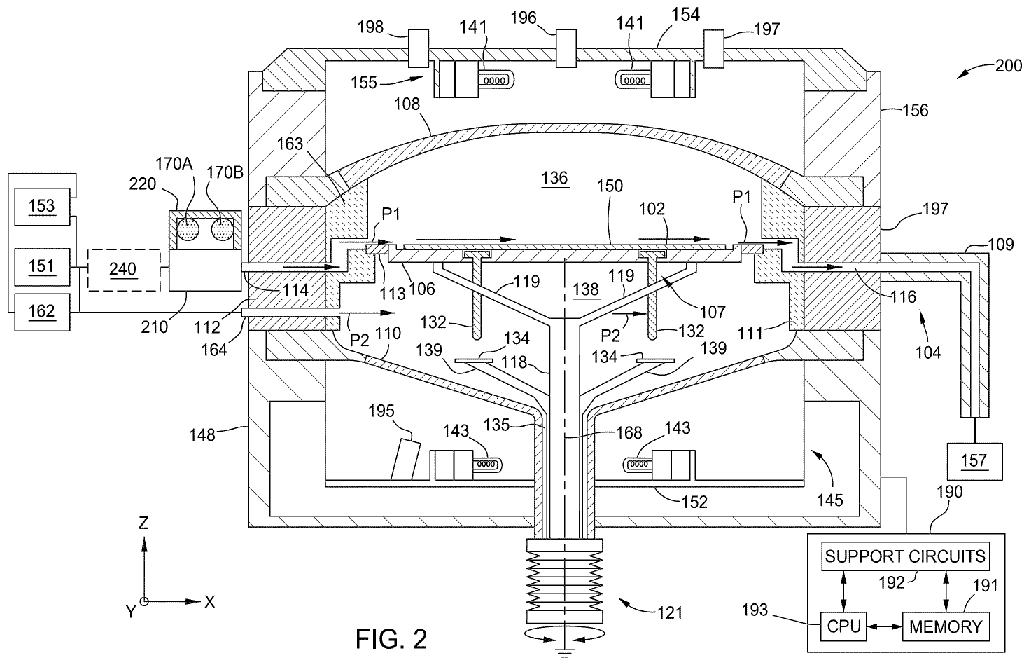

FIG. 2 is a partial schematic side cross-sectional view of a processing chamber 200, according to one or more embodiments. The processing chamber 200 is similar to the processing chamber 100 shown in FIG. 1, and includes one or more of the aspects, features, components, properties, and/or operations thereof. The processing chamber 200 is shown in a processing condition in FIG. 2.

The processing chamber 200 includes one or more UV energy sources 170A, 170B (a plurality is shown in FIG. 2), a gas box 210, and a lamp support structure 220. In one or more embodiments the UV energy sources 170A and 170B are deposited outwardly of the chamber liners 163, 111 outside of the upper and lower chamber bodies 156, 148, and are supported by the lamp support structure 220 which is coupled to the flow module 112. The lamp support structure 220 can block an outer side of the UV energy sources 170A, 170B and can be reflective to reflect UV light toward the gas box 210. It is contemplated that the lamp support structure can be coupled to the gas box 210, the flow module 112, the upper body 156, and/or the lower body 148. The UV energy sources 170A, 170B are disposed above the gas box 210. Although processing chamber 200 shows two UV energy sources, it is contemplated that any number UV energy sources can be used such as 1 UV energy source, 2 UV energy sources, 4 UV energy sources, or 5 UV energy sources. In addition, any number of lamp support structures 220 can be used. In one embodiment which can be combined with other embodiments, two lamp support structures 220 can be coupled to the processing chamber 200, one lamp support structure is positioned above the gas box 210 as shown, the second lamp support structure 220 is positioned below the gas box 210 so that UV energy sources can be disposed above and below the gas box 210. In one or more embodiments, the processing chamber 200 includes a remote plasma source (RPS) 240. It is contemplated that the RPS 240 can be fluidly coupled to the gas box 210. The RPS 240 may generate a plasma outside of the processing volume 136. In some embodiments, the RPS 240 is located upstream of the gas box 210. In some embodiments, the RPS 240 is located downstream of the gas box 210.

In one embodiment which can be combined with other embodiments, at least one of the UV energy sources 170A, 170B is operable to emit a UV light having a peak wavelength and/or photon energy described above.

In one embodiment which can be combined with other embodiments, the UV energy sources 170A, 170B emit the UV light at the same peak wavelength and/or same photon energy. In one or more embodiments the UV energy sources 170A, 170B are configured to emit UV light at different peak wavelengths and/or different photon energies. The peak wavelength of each UV energy source 170A, 170B, is able to be tuned independently from one another.

The one or more process gases P1 flow through the gas box 210 where the one or more process gases P1 are exposed to UV light emitting from the UV energy sources 170A, 170B. The UV light is absorbed by the process gases P1 and activates the process gases P1 so that the process gases deposit and/or etch a layer of material on the substrate 102 after flowing into the process volume 136 and over the substrate 102. At least part of the gas box 210 can be formed of quartz and can be transmissive for ultraviolet light. The UV energy sources 170A, 170B are shown as above the gas box 210. The UV energy sources 170A, 170B and/or additional UV energy sources 170A 170B can be disposed below the gas box 210.

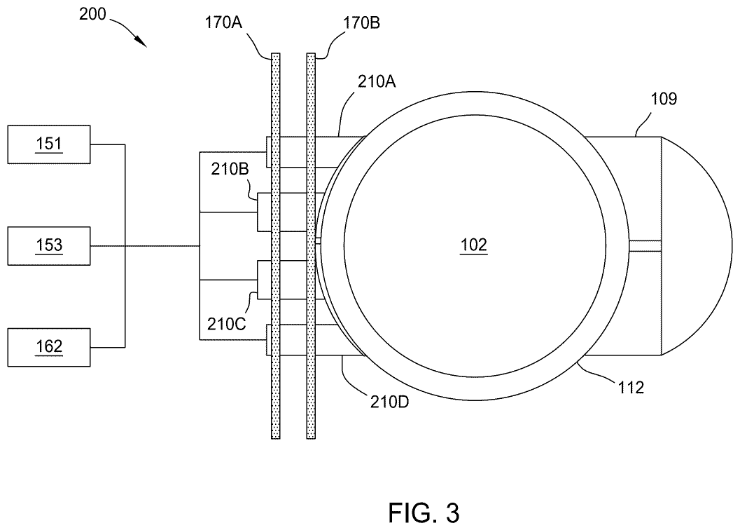

FIG. 3 is a partial schematic top cross-sectional view of the processing chamber 200 shown in FIG. 2, according to one or more embodiments. Certain components of processing chamber 200 such as the upper body 156, the lower body 148, the lid 154, and the lamp support structure 220 are not shown for visual clarity purposes.

The UV energy sources 170A, 170B are disposed above the gas boxes 210A, 210B, 210C, 210D. It is contemplated that although four gas boxes are shown in FIG. 3, any number (such as 1, 2, 3, or more than 4) of gas boxes can be used.

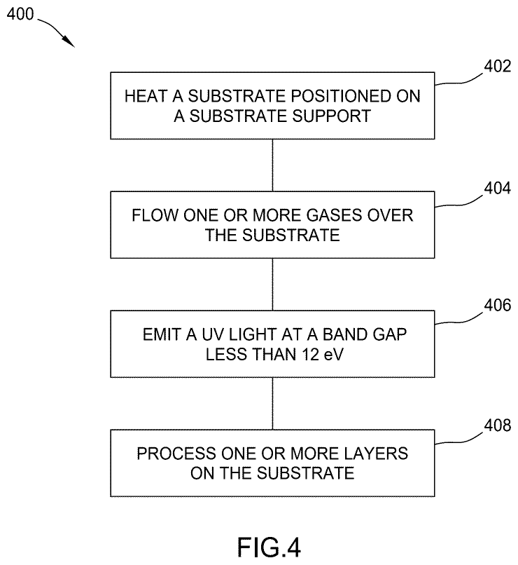

FIG. 4 is a schematic flow chart view of a method 400 of processing a substrate, according to one or more embodiments. The method 400 can be conducted in relation to any of the previously described processing chambers 100, 200, or other processing chambers.

Operation 402 includes heating a substrate positioned on a substrate support. In one or more embodiments, the substrate is heated to a target temperature that is 500 degrees Celsius or less.

Operation 404 includes flowing one or more process gasses over the substrate.

Operation 406 includes irradiating the one or more process gases a UV light at peak wavelength having a photon energy of less than 12 eV such as a photon energy of 4.5 eV or less. In one embodiment which can be combined with other embodiments, operation 406 occurs prior to operation 404. In one embodiment which can be combined with other embodiments, operation 406 occurs substantially simultaneously with operation 404. The wavelength and/or the photon energy can be equal to any of the values described for the wavelengths and/or the photon energies above. In one embodiment which can be combined with other embodiments, the process gas from operation 404 is exposed to the UV light and absorbs the photons which activates the process gases. In one embodiment which can be combined with other embodiments, the UV light photons are absorbed by first surfaces (e.g., semiconductor surfaces) of the substrate relative to second surfaces (e.g., dielectric surfaces) of the substrate to activate the first surfaces for selective processing (e.g., deposition, cleaning, and/or etching) of the first surfaces relative to the second surfaces.

In one embodiment which can be combined with other embodiments, multiple UV lights are emitted such as two UV lights, three UV lights, or eight UV lights. In one embodiment which can be combined with other embodiments, the multiple UV lights are emitted having the same wavelength and/or photon energy. In one embodiment which can be combined with other embodiments the multiple UV lights are emitted having different wavelengths and/or photon energies. For example, a first UV energy source can emit a first UV light having a first peak wavelength and/or a first photon energy, a second UV energy source can emit a second UV light having a second peak wavelength and/or a second photon energy, and a third UV energy source emits a third UV light having a third wavelength and/or a third photon energy. The multiple UV lights can be emitted simultaneously and/or sequentially. As an example, the first peak wavelength and/or the first photon energy can be used for the first UV energy source 170A during a first process (e.g., a first deposition process using a first recipe), the second peak wavelength and/or the second photon energy can be used for the second UV energy source 170B during a second process (e.g., an etching process using a second recipe), the third peak wavelength and/or the third photon energy can be used for the third UV energy source 170C during a third process (e.g., a cleaning process using a third recipe), and/or a fourth peak wavelength and/or the fourth photon energy can be used for a fourth UV energy source 170D during a fourth process (e.g., a second deposition process using a fourth recipe).

Operation 408 includes processing one or more film portions on the substrate. In one or more embodiments, Operation 406 occurs prior to, and/or concurrently with, operation 408. In one or more embodiments, operations 406 and 408 occur substantially simultaneously. The processing can include depositing the one or more film portions on the substrate, etching the one or more film portions on the substrate, and/or cleaning the one or more film portions on the substrate.

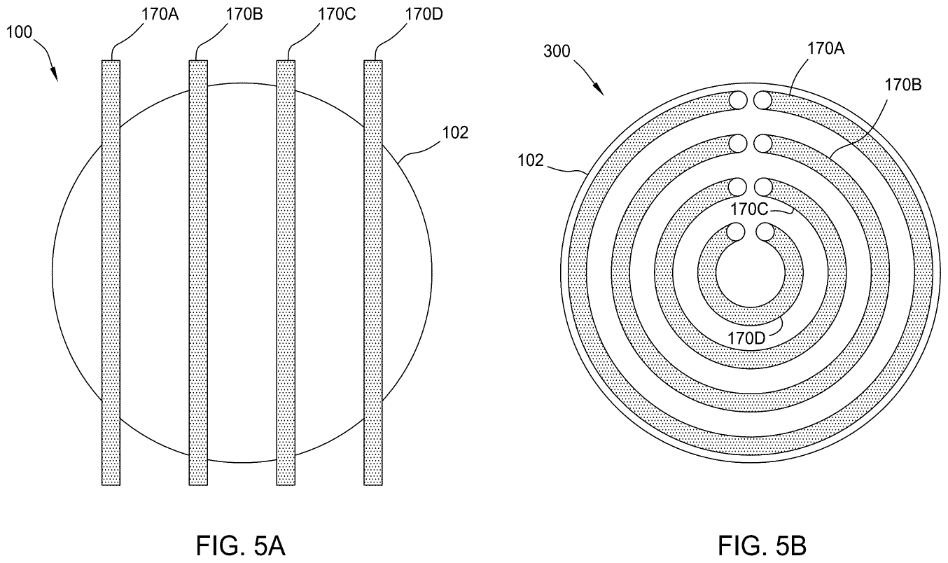

FIG. 5A is a partial schematic top view of the processing chamber 100 shown in FIG. 1, according to one or more embodiments. The UV energy sources 170A, 170B, 170C, 170D and the substrate 102 of processing chamber 100 are shown, and other components are not shown, for visual clarity purposes.

In one embodiment which can be combined with other embodiments the UV energy sources 170A, 170B, 170C, 170D are UV lamp rods suspended above the substrate. In embodiment which can be combined with other embodiments the UV lamp rods are disposed above the first plate 108 (FIG. 1) and are coupled to the lid 154 or the upper body 156. The UV lamp rods can be coupled to and/or supported on the first plate 108.

FIG. 5B is partial schematic top view of a processing chamber 300, according to one or more embodiments. The processing chamber 300 is similar to the processing chamber 100 shown in FIG. 1, and includes one or more of the aspects, features, components, properties, and/or operations thereof. The UV energy sources 170A, 170B, 170C, 170D and the substrate 102 of processing chamber 300 are shown, and other components are not shown, for visual clarity purposes.

In embodiment, which can be combined with other embodiments, the UV energy sources 170A, 170B, 170C, 170D are UV lamp ring segments suspended above the substrate. In embodiment which can be combined with other embodiments the UV lamp ring segments are disposed above the first plate 108 (FIG. 1) and are coupled to the lid 154 or the upper body 156. Although FIG. 5B shows four UV lamp ring segments, it is contemplated that different numbers and geometries of UV energy sources could be used. For example, in embodiment which can be combined with other embodiments 2 UV lamp ring segments are used. In embodiment which can be combined with other embodiments a single spiral UV lamp is used. In embodiment which can be combined with other embodiments a single UV plate is used. In embodiment which can be combined with other embodiments a UV plate is surrounded by multiple UV lamp ring segments

The present disclosure contemplates that the UV energy sources described herein can be linear (as shown in FIG. 5A) and/or can be curved (as shown in FIG. 5B.

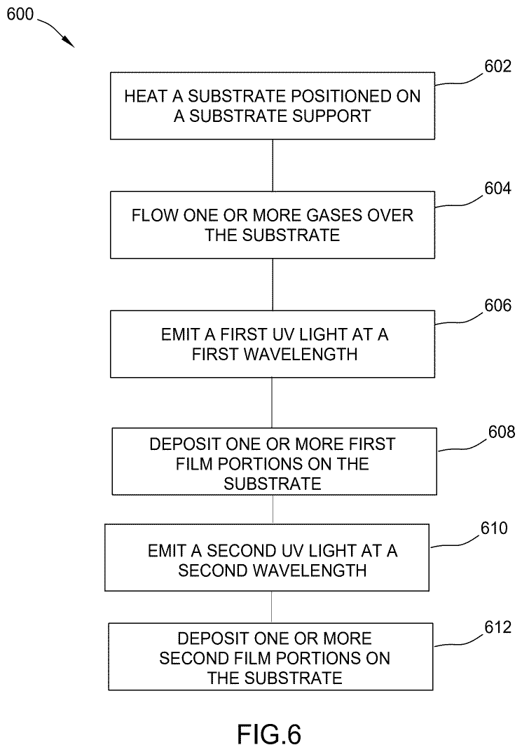

FIG. 6 is a schematic flow chart view of a method 600 of processing a substrate, according to one or more embodiments. The embodiments of method 600 facilitate deposition of films with tailored film compositions, among other benefits. The method 600 can be conducted in relation to any of the previously described processing chambers 100, 200, or other processing chambers.

Operation 602 includes heating a substrate positioned on a substrate support. In one or more embodiments, the substrate is heated to a target temperature that is 500 degrees Celsius or less.

Operation 604 includes flowing one or more process gasses over the substrate. In one or more embodiments which can be combined with other embodiments, the one or more process gases includes a mixture of at least two different process gases including a first process gas and a second process gas. The first and second process gases may include film precursors and/or dopants, such as silane, germane, and phosphine. It is contemplated that the first process gas and the second process gas can comprise any combination of gases for use in epitaxial growth. In one non-limiting example, the first gas is a film material such as silane, and the second gas is dopant such as phosphine. Carrier gases, as necessary, may also be utilized.

Operation 606 includes irradiating the one or more process gases with a first UV light at a first peak wavelength. In one or more embodiments, the first UV light is emitted from one or more UV light sources. In one or more embodiments, the first peak wavelength is within a range of 160 nm to 450 nm. The first UV light is emitted on the one or more process gases. In one or more embodiments, the first peak wavelength of the UV light has a first photon energy. The first photon energy is operable to activate the first process gas relative to the second process gas. For example, if the first process gas is a gas comprising silicon then the one or more UV light sources emit the first UV light with a first photon energy directed to preferentially activate the silicon in the first process gas, relative to other compounds or elements in the first process gas or second process gas. The first UV light is selectively absorbed by and activates the silicon material in the first process gas. The first UV light breaks the bonds with the silicon in the first process gas, to preferentially deposit silicon relative to other species. In some embodiments, the UV light is emitted at the first peak wavelength to activate the first process gas relative to, or to a greater extent than, the second process gas. In one example, the second process is substantially inactivated. In another example, only a portion of the second process gas is activated, such as 5-10%, or 10-20%, or 25-75%, or more than 50%, or less than 50%, or less than 25%. Thus, the composition of the deposition film can be controlled by selectively changing UV emission to cause increased or decreased reactivity.

Operation 608 includes depositing one or more film portions on the substrate. In one or more embodiments, operation 606 is performed prior to operation 608. In some embodiments, operations 606 and 608 are performed substantially simultaneously. The one or more process gases are flowed over the substrate after being exposed to the first UV light with the first peak wavelength. In some embodiments, the first process gas in the one or more process gases is activated by the first UV light and deposits one or more film portions over the substrate. In some embodiments, substantially only the first process gas in the one or more process gases deposits one or more film portions on the substrate because the first process gas is the only process gas activated in operation 606. For example, if the first process gas is a gas comprising silicon and the second process is a gas comprising phosphorous, then the first UV light is emitted at a wave length that is directed towards activating the first process gas to a greater extent than the second process gas. Therefore, as the first process gas and the second process gas flow over the substrate, the first process gas deposits a layer of silicon on the substrate, while the phosphorus in the second process gas is not deposited on the substrate, or is deposited on the substrate to a lesser extent than the silicon. It is to be understood that the above example, incorporate silicon and phosphorus, is only for purposes of explanation, and other elements or compounds may benefit from aspects of the disclosure.

Operation 610 includes irradiating the one or more process gases a second UV light at a second peak wavelength. In one or more embodiments, the second UV light at is emitted from one or more UV light sources. In some embodiments, the second UV light is emitted from the first UV light source, but a second UV light may be emitted from a second UV light source. The one or more UV light sources are disposed inside a processing chamber or outside the processing chamber. In some embodiments, the UV In one or more embodiments, the second peak wavelength is within a range of 160 nm to 450 nm. The second peak wavelength is different from the first peak wavelength. The second UV light is emitted on the one or more process gases. In one or more embodiments, the second peak wavelength of the UV light has a second photon energy. The second photon energy is operable to activate the second process gas. For example, if the second process gas is a gas comprising phosphorus then the one or more UV light sources emit the second UV light with a second photon energy directed to preferentially activate the phosphorus in the second process gas, or to activate the second process gas to a greater extent than the first UV light was capable of activating the second process gas. The second UV light is selectively absorbed by and activates the phosphorus material in the second process gas. The second UV light breaks the bonds with the phosphorus in the second process gas, resulting in greater incorporation of phosphorus into the deposited film. In one example, the first process is substantially inactivated. In another example, only a portion of the first process gas is activated, such as 5-10%, or 10-20%, or 25-75%, or more than 50%, or less than 50%, or less than 25%. In another example, the first process gas may have approximately the same level of activation as in operations 606 and 608, and only the activation of the second process gas is changed in operation 610 and 612.

Operation 612 includes depositing one or more film portions on the substrate. In one or more embodiments, operation 610 is performed prior to operation 612. In some embodiments, operations 610 and 612 are performed substantially simultaneously. In some embodiments, the one or more process gases are flowed over the substrate after being exposed to the second UV light with the second peak wavelength. In some embodiments, which can be combined with other embodiments, the second process gas in the one or more process gases is activated by the second UV light and deposits one or more film portions over the substrate. In some embodiments, only the second process gas in the one or more process gases deposits one or more film portions on the substrate because the second process gas is the only process gas activated in operation 610. In other embodiments, material from both the first process gas and the second process gas is deposited on the substrate in operation 612, but at a different composition or ratio than the film portions deposited in operation 608. Moreover, while the above description is presented with respect to “film portions”, it is to be understood that method 600 may deposit a single film, having a graded composition.

In some embodiments, which can be combined with other embodiments, operations 606, 608, 610, and 612 are all performed substantially simultaneously. The intensity of the first UV light and the intensity of the second UV light can be tuned allow for varying deposition amounts by the first process gas and the second process gas. For example, if the first process gas is a gas comprising silicon and the second process gas is a gas comprising phosphorus, the mixture of the first process gas and the second process gas can be flowed simultaneously over the substrate. As that is happening, the first UV light at a first peak wavelength and the second UV light at a second peak wavelength may be simultaneously emitted over the mixture of the first process gas and the second process gas. If a user wanted to deposit a layer of mostly silicon over the substrate, then the intensity of the first UV light can be increased and the intensity second UV light can be decreased or turned off entirely. This will cause the mixture of first process gas and the second process gas to mostly only deposit the material in the first process gas, such as silicon, while the second process gas does not deposit anything.

If the user wants to deposit a layer of mostly phosphorus over the substrate, then the intensity of the second UV light can be increased and the intensity first UV light can be decreased or turned off entirely. This will cause the mixture of first process gas and the second process gas to mostly only deposit the material in the second process gas, such as phosphorus, while the first process gas does not deposit anything. If a user wanted to deposit a layer of material with but silicon and phosphorus, then the intensity of the first UV light and the second UV light can be increased. This will cause the mixture of first process gas and the second process gas deposit the material in both the first process gas and the second process gas, such as both silicon and phosphorus. The intensity of the first UV light and the second UV light can be tuned at different intensities leading to film portions of material being deposited on the substrate having various ratios of the first material in the first process gas and the second material in the second process gas. Although the first material is described as silicon and the second material is described as phosphorus in method 600, it should be understood that the materials were described as such for illustrative purposes and method 600 should not be interpreted as being limited to those materials.

The first UV light and the second UV light can come from a single UV the same UV light source, or from different UV light sources. It is contemplated that method 600 can be performed using the processing chamber 100 and the processing chamber 200, another processing chamber that is able to perform the method 600. Although method 600 is described using two different process gases and two different UV lights, it should be known that this is done for illustrative purposes and that any number of process gases or UV lights may be used, such as three process gases and three UV lights, or 4 process gases and 4 UV lights.

Benefits of the present disclosure include enhanced gas activation and/or surface activation, selective activation for selective processing, (e.g., deposition, cleaning, and/or etching), increased processing rates, and enhanced processing uniformity, such as for low temperature operations that use relatively low target temperatures for substrates. Such benefits can be facilitated, for example, for Complementary metal-oxide-semiconductor (CMOS) operations.

It is contemplated that one or more aspects disclosed herein may be combined. As an example, one or more aspects, features, components, operations and/or properties of the processing chamber 100, processing chamber 200, the substrate 102, the lid 154, the first plate 108, the UV energy sources 170A-170F, the gas boxes 210A-210D the lamp support structure 220, the method 400, the processing chamber 300, the UV energy source 170A-170D implementations described for FIG. 5A, the UV energy source 170A-170D implementations described for FIG. 5B, and/or method 600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for semiconductor manufacturing, comprising:
a chamber body;
a substrate support disposed in a processing volume; and
a gas inlet fluidly coupled to the chamber body to provide gas to the processing volume, the gas inlet comprising:
one or more UV energy sources for irradiating gas within the gas inlet prior to the gas entering the processing volume, wherein the one or more UV energy sources comprise a first UV energy source producing light having a first peak wavelength and second UV energy source producing light having a second peak wavelength different from the first peak wavelength.

2. The processing chamber of claim 1, wherein the first peak wavelength has a first photon energy and a second peak wavelength has a second photon energy different than the first photon energy, wherein the first photon energy is operable to activate a first process gas, and the second photon energy is operable to activate a second process gas, wherein the first process gas and the second process gas are different in composition.

3. The processing chamber of claim 1, further comprising:
a gas outlet disposed opposite the gas inlet, wherein the gas inlet is configured to flow a processing gas horizontally over the substrate support towards the gas outlet.

4. The processing chamber of claim 2, wherein the first peak wavelength and the second peak wavelength are within a range of 160 nm to 450 nm.

5. The processing chamber of claim 2, wherein the first photon energy and the second photon energy are less than 12 eV.

6. The processing chamber of claim 2, wherein the one or more UV energy sources further comprise:
a third UV energy source producing light having a third peak wavelength, wherein the first peak wavelength, the second peak wavelength, and the third peak wavelength are different.

7. The processing chamber of claim 6, wherein the one or more UV energy sources further comprise:
a fourth UV energy source producing light having a fourth peak wavelength, wherein the first peak wavelength, the second peak wavelength, the third peak wavelength, and the fourth peak wavelength are different.

8. The processing chamber of claim 1, further comprising a remote plasma source (RPS) disposed outside the processing volume, wherein the RPS is fluidly coupled to the gas inlet upstream of the gas inlet.

9. The processing chamber of claim 8, wherein the RPS is disposed upstream of the one or more UV energy sources.

10. The processing chamber of claim 8, wherein the remote plasma source is disposed downstream of the one or more UV energy sources.

11. The processing chamber of claim 2, wherein the first peak wavelength and the second peak wavelength are tunable independently from one another.

12. The processing chamber of claim 11, further comprising one or more additional UV energy sources outside the processing volume and configured to direct UV light into the processing volume.

13. A method of substrate processing, comprising:
heating a substrate positioned on a substrate support;
flowing one or more process gases over the substrate;
irradiating the one or more process gases with a first UV light having a first peak wavelength;
depositing one or more first film portions on the substrate using the one or more process gases irradiated with the first UV light;
irradiating the one or more process gases with a second UV light having a second peak wavelength different than the first peak wavelength; and
depositing on or more second film portions on the substrate using the one or more process gases irradiated with the second UV light, the second film portion having a different atomic composition from the first film portion.

14. The method of claim 13, wherein the one or more process gases comprises a first process gas and a second process gas, wherein the first process gas has a different atomic composition from the second process gas.

15. The method of claim 14, wherein emitting a first UV light with a first peak wavelength comprises emitting the first UV light on the first process gas and the second process gas and activating the first process gas relative the second process gas.

16. The method of claim 14, wherein emitting a second UV light with a second peak wavelength comprises emitting the second UV light on the first process gas and the second process gas and activating the second process gas relative the first process gas.

17. The method of claim 15, wherein depositing one or more first film portions over the substrate comprises flowing the first process gas and the second process gas over the substrate, and depositing one or more first film portions over the substrate, the one or more first film portions comprising a first composition deposited by the first process gas.

18. The method of claim 16, wherein depositing on or more second film portions on the substrate comprises flowing the first process gas and the second process gas over the substrate, and depositing one or more second film portions over the substrate, the one or more second film portions comprising a second composition deposited by the second process gas.

19. The method of claim 13, wherein the substrate is heated to a temperature less than 500 degrees Celsius.

20. A non-transitory computer readable medium, the non-transitory computer readable medium comprising instructions that when executed by a processor of a system cause a system to:
heat a substrate positioned on a substrate support;
flow one or more process gases over the substrate;
irradiate the one or more process gases with a first UV light with a first peak wavelength;
deposit one or more first film portions on the substrate using the one or more process gases irradiated with the first UV light;
irradiate the one or more process gases with a second UV light with a second peak wavelength different than the first peak wavelength; and
deposit on or more second film portions on the substrate using the one or more process gases irradiated with the second UV light, the second film portion having a different atomic composition from the first film portion.
